(19) United States
(12) Patent Application Publication
(10) Pub. No.: US 2015/0376767 A1
(43) Pub. Date: Dec. 31, 2015

(54) PLASTIC COMPONENT COATED WITH AN EMBEDDED PVD LAYER

(71) Applicant: OERLIKON SURFACE SOLUTIONS AG, TRÜBBACH, Trübbach (CH)

(72) Inventors: Carlos Ribeiro, Ho Chi Minh City (VN); Sascha Baur, Messkirch (DE)

(21) Appl. No.: 14/437,918

(22) PCT Filed: Oct. 22, 2013
(86) PCT No.: PCT/EP2013/003175

§ 371 Date: Aug. 5, 2015

(30) Foreign Application Priority Data
Oct. 23, 2012 (DE) 10 2012 020 742.5

(51) Int. Cl. C23C 14/20; C23C 28/00; C23C 14/02; C23C 14/58

(52) U.S. Cl. CPC C23C 14/20; C23C 14/58; C23C 28/00; C23C 14/024

(57) ABSTRACT

A plastic material piece including a substrate and a layer system applied upon the substrate. Directly on the substrate there is applied a first lacquer layer and subsequent to the lacquer layer a PVD layer system. The PVD layer system includes at least a first layer, a second layer and a third layer, whereby the first layer lies onto the first lacquer layer and is realized as an adherence layer, the second layer is realized as a stabilizing buffer layer, and the third layer is realized as a color defining layer.

The present invention is directed on plastic material pieces comprising a coating. The invention, especially addresses such pieces, which are perceived for outdoor use and which are thus exposed to defer ambient conditions. Such pieces include at special but not exclusively such plastic material pieces, which are provided at the outside of vehicles. For such plastic material pieces, the optically pleasant surfaces must be kept also as longer use.

It is known to provide upon plastic material pieces a metallic layer by means of galvanic methods and thus to realize surfaces with a metallic appearance. Such galvanic methods are today critically considered with respect environmental compatibility as the electronics, which are used by such methods, are highly toxic. Thus, expensive and extensive techniques are used to avoid leakage of such toxic substances and on the other hand to depollute used electrolytes in an environmentally responsible manner.

Alternatively, coating of plastic material surfaces by means of vacuum coating is known especially by means of deposition out of the gaseous phase. Such methods lead to a PVD layer, whereby PVD stands for physical vapor deposition.

The EP 1 736 566 describes a method according to which a polymer layer is applied to the surface of a thermoplastic substrate to result in a metallic finish, whereby upon the addressed polymer layer there is applied, by means of PVD, a metallic layer, e.g. of chromium. Curing of the polymer layer is e.g. realized by exposure to UV-radiation. The EP 1 736 566 does not explicitly address the field of use. The skilled artisan, nevertheless, gets the impression, the pieces addressed in the EP 1 736 566 being articles of daily use as for example, containers as e.g. used in cosmetics industries. Environmental influences upon such pieces appear rather of secondary importance. This is far remote for subject matter as addressed in the frame of the present invention, namely from coated plastic material pieces for vehicle appliances.

In the context with coating of plastic material pieces for vehicle appliances, a layer structure appears to be especially promising in which a PVD layer is applied between a lacquer base layer on the plastic material piece and a cover lacquer layer applied upon the PVD layer. Such a layer system is disclosed in the DE 19745407. There a method is described, according to which plastic material pieces for vehicles are coated, which comprises the following steps:
applying a lacquer layer from a powder cure lacquer,
applying a high gloss layer of a metal alloy or of a metal compound, by means of a magnetron in vacuum,
applying a transparent wear resistant cover lacquer layer.

Thereby, it is clear that it is the cover lacquer layer, which is predominantly exposed to environmental influences. In the DE 19745407 there is thus proposed, to apply this cover lacquer layer by means of a CVD technique. With respect to the base lacquer layer, one must predominantly mind that the base lacquer layer well adheres on the substrate and that the PVD layer well adheres on the base lacquer layer. The good adherence of the base lacquer layer on the substrate is achieved according to the DE 19745407 by making use of a powder cure lacquer as the base lacquer layer. This appears in the DE 19745407 mandatory. The good adherence of the PVD layer upon the base lacquer is achieved according to the DE 19745407 in that before magnetron appliance of the high gloss layer, there is performed a pre-treatment in vacuum especially by applying an adherence promoting layer. Nevertheless, there is not described what could be used as adherence promoting layer and how such layer might be applied in vacuum.

It is an object of the present invention to propose a coated plastic material piece for vehicles, the coating thereof providing a desired appearance of the plastic material piece, whereby the surface has a high weather proofness and is protected at least to a certain degree against environmental influences as e.g. with respect to stone-chipping, and whereby further the coating may be provided economically, at low costs and ecologically friendly.

According to the present invention, this object is resolved by means of a coated plastic material piece according to claim 1. The inventor has recognized that a coated plastic material piece, which is stable with respect to environmental influences, may be realized in that an at least 3-layer PVD layer is used, which is applied upon a base lacquer layer. Preferably, a cover lacquer layer is applied upon the at least 3-layer PVD-layer. The core of this at least 3-layer PVD-layer is a thick buffer layer in the central area, which provides stability for the entire layer system. Between buffer layer and base lacquer layer there is provided, according to the invention, an adherence layer. A color defined layer is applied upon the buffer layer according to the invention. It has shown up that due to this structure according to the invention, one may abstain from applying the expensive powder cure lacquer and from the respective expensive method. It is assumed that the buffer layer leads to mechanic characteristics of the PVD layer system, which impede flaking of the base lacquer from the substrate surface. Especially the element of the groups IVb, Vb, and VIb of the periodic system of elements and aluminum as well as mixtures thereof and/or their respective nitrides, oxides and/or carbide are materials selectable for the PVD layer system. Doping with elements of the groups IIIA and/or IVA of the periodic system of elements may be advantageous.

As a base lacquer e.g. a photosensitive lacquer may be used, which may be cross-linked by means of UV-radiation and which may be applied by a simple spray method.

Upon the color defined PVD-layer, there is preferably provided a cover lacquer layer, which protects the subjacent PVD-layer chemically e.g. with respect to corrosion as well as mechanically, e.g. with respect to stone-chipping.

As a cover lacquer e.g. a transparent photo sensitive lacquer may be used, which may be cross-lined by UV-radiation and which may be applied by a simple spraying method. According to an especially preferred embodiment, the UV cross-linking lacquer, additionally comprises UV-blocking substances. By means of the UV-blocking substances in fact the time during which the cover lacquer for complete cross-linking has to be exposed, increases. Nevertheless, plastic material pieces which are applied at the outside of vehicles, are frequently exposed to intense solar radiation. The provision of UV-blocking substances in the UV cross-linking cover lacquer leads to a slower aging (e.g. yellowing) due to the blocking effect and thereby leads to a longer lasting of an optical pleasing appearance of the plastic material piece.

The invention shall now be explained by means of examples and with a help of the FIGURE in details.

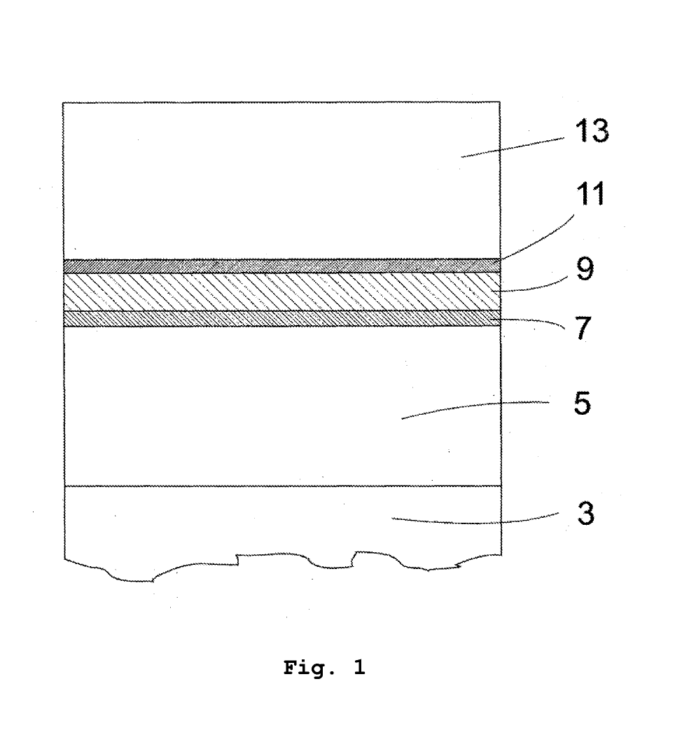

FIG. 1 shows schematically the layer structure according to an embodiment of the present invention.

According to a first embodiment of the present invention there is applied on a plastic material substrate a base lacquer layer of 10 μm thickness. To do so, the substrate is first cleaned, dried and discharged before the UV cross-linking lacquer is sprayed on by means of a lacquering arrangement. The resulting substrates are then and according to the example freed from solvents by means of IR-radiation loading and are dried. Subsequently, there is performed an intense UV-radiation loading so as to cross-link the base lacquer layer.

After having applied, dried and cross-linked the base lacquer layer, the substrate is introduced into a PVD coating facility. In the present example, the coating facility is a magnetron sputtering facility. The material to be coating applied, is sputtered from a so called sputter target by means of ion bombardment and deposited upon the substrate to be coated. In the present example an inline facility is used, in which the substrate first passes a chromium target. Thereby a chromium layer is sputter deposited onto the base lacquer with a thickness of 30 nm. Subsequently, the substrate is passed a zirconium target in the PVD coating facility and there is sputter deposited a buffer layer of zirconium having a thickness of 100 nm. Finally, the substrate is again passed a chromium target, which leads to the sputter deposition of a color layer of chromium having a thickness of 60 nm. After having applied the desired PVD layer system according to the invention onto the substrate, the substrate is locked-out from the PVD coating facility.

The buffer layer is essential for the stability of the overall layer system, which buffer layer being realized in the present example by the zirconium layer. As it has been recognized by the inventors, it is further advantageous to impress an inner structure to the buffer layer. According to one embodiment of the present invention, the buffer layer is constructed from several different layer materials of different hardness and/or elasticity. In the present example, nevertheless, only zirconium was used as layer material of the buffer layer. In order to impress an inner structure to the buffer layer, the process parameters were modulated during the coating. On one hand, the coating was divided into six coating intervals, which were separated by coating pauses, whereby a coating pause directly subsequent to a coating interval was selected approximately half the length of the coating interval. On the other hand, the current intensity was varied. Thereby, the current intensity of the last three coating intervals was reduced by approximately 20% with respect to the current intensity during the first three coating intervals. In the present example, for the first three coating intervals 28 amperes were applied, whereas for the last three coating intervals 24 amperes were applied. By this procedure, there is presumably introduced into the buffer layer a deepness depending density distribution so that more density areas alternate with less density areas and thus the buffer layer is stabilized. Preferably, the addressed sub-layer, which result therefrom are to be resolved by means of SEM.

According to a preferred embodiment of the present invention, there is now additional deposited a cover lacquer layer of UV cross-linking lacquer with a thickness of 20 μm, which is preferably provided with one or more than one UV-blocking substances. Thereby, a method may be used which accords with the method described for the base lacquer layer. However, the PVD coated surface needs not to be cleaned, provided that the PVD coated plastic material piece is substantially coated with lacquer subsequent to the PVD coating, immediately.

It is a particular advantage of this form of realization that the PVD layer does not form an aluminum surface for the cover lacquer layer.

According to a second form of realization of the present invention, there is as well provided a 10 μm thick base lacquer layer onto the plastic material substrate. To do so, the substrate is first cleaned, dried and discharged before the UV cross-linking lacquer is sprayed on by means of a lacquering arrangement. The thus resulting substrates are then in the example freed from possible solvents and dried by means of exposing to IR-radiation. Subsequently, an exposure to an intense UV-radiation is performed so as to cross-link the base lacquer layer.

After the base lacquer layer having been applied, dried and cross-linked, the substrate is locked into a PVD coating facility. In the present example, the coating facility is a magnetron sputter facility. The material to be deposited is sputtered from a so called sputter target by means of ion bombardment and deposits upon the substrates to be coated. In the present example, there is used an inline facility in which the substrate is first passed along a chromium target. Thereby, a chromium layer is deposited upon the base lacquer with a thickness of 60 nm. Preferred are thicknesses of this layer from 20 nm to 100 nm.

Subsequently, the substrate is passed along an aluminum target in the PVD coating facility and a buffer layer of aluminum having a thickness of 200 nm is sputter deposited. Preferred are thicknesses of this layer between 80 nm and 250 nm.

The concluding color layer is finally applied in two parts. First, again, by sputtering, a 60 nm thick chromium layer is sputter deposited. This results in a blueish colored surface. Preferred are layer thicknesses of 20 nm to 100 nm. Finally, the substrate is again passed along aluminum targets, which leads to sputter deposition of a 35 nm thick layer of aluminum and brightens the color. Preferred are layer thicknesses of 10 nm to 50 nm.

Also in this second form of realization, it may be advantageous to provide a cover lacquer layer. According to this preferred form of realization of the present invention, there is now deposited a 20 μm thick cover lacquer layer of UV cross-linking lacquer, which especially preferred is provided with one or more UV-blocking substances. Thereby, a method may be applied according to the method described for the base lacquer layer. Nevertheless, the PVD coated surface must not be cleaned, provided that the PVD coated substrate is coated with lacquer substantially subsequent to the PVD coating, immediately. Because the outermost PVD layer is now an aluminum layer and aluminum easily links to oxygen, an aluminum oxide layer may be formed, which has an influence on the adherence of the cover lacquer layer upon the PVD layer. Thus, the first realization form of the present invention as described above has the advantage that one may completely resign to use aluminum.

The thus resulting plastic material piece may e.g. be applied in the inside area and/or in the outside area of vehicles. As examples for the outside area, ornamental patterned trim and radiator grill may be addressed.

What is claimed is:

1-10. (canceled)

11. Plastic material piece comprising a substrate and a layer system applied upon the substrate, whereby directly on the substrate there is applied a first lacquer layer and subsequent to the lacquer layer a PVD layer system, characterized by the fact that the PVD layer system comprises at least a first layer, a second layer and a third layer, whereby the first layer lies onto the first lacquer layer and is realized as an adherence layer, the second layer is realized as a stabilizing buffer layer, and the third layer is realized as a color defining layer, wherein the adherence layer comprises chromium.

12. Plastic material piece according to claim 11, characterized by the fact that the adherence layer comprises a chromium layer.

13. Plastic material piece according to claim 11, characterized by the fact that the buffer layer comprises zirconium.

14. Plastic material piece according to claim 13, characterized by the fact that the buffer layer comprises a zirconium layer.

15. Plastic material piece according to claim 11, characterized by the fact that the base lacquer layer has a thickness of between 5 μm and 40 μm, preferably of 10 μm.

16. Plastic material piece according to claim 11, characterized by the fact that there is provided upon the PVD layer a cover lacquer layer.

17. Plastic material piece, according to claim 11, characterized by the fact that the cover lacquer layer comprising UV blockers.

18. Plastic material piece according to claim 11, characterized by the fact that the buffer layer comprises an inner structure, which is visible as layers in SEM.

19. Plastic material piece according to claim 18, characterized by the fact that the layers are different in material concentrations and/or deepness depending density distribution.

20. Plastic material piece according to claim 11, characterized by the fact that the color layer comprises chromium and/or aluminum, and wherein the color layer is preferably formed by a chromium layer and an overlying aluminum layer.

21. Motor vehicle comprising in the interior area and/or in the outside area a plastic material piece according to claim 11.
